(19) United States
(12) Patent Application Publication
(10) Pub. No.: US 2026/0123023 A1
(43) Pub. Date: Apr. 30, 2026

(54) SILICIDE REGIONS AND THE METHODS OF FORMING THE SAME

(71) Applicant: Taiwan Semiconductor Manufacturing Co., Ltd., Hsinchu (TW)

(72) Inventors: Yuting Cheng, Taoyuan City (TW); Tzu Pei Chen, Taipei City (TW); Po-Chin Chang, Taichung City (TW); Sung-Li Wang, Zhubei City (TW); Hsin Wang, New Taipei City (TW); Olivia Pei-Hua Lee, Hsinchu (TW); Chia-Hung Chu, Taipei City (TW); Wei-Yip Loh, Hsinchu (TW); Hao-Chin Huang, Kaohsiung City (TW)

(21) Appl. No.: 19/066,759

(22) Filed: Feb. 28, 2025

Related U.S. Application Data
(60) Provisional application No. 63/711,958, filed on Oct. 25, 2024.

(51) Int. Cl. H10D 84/01; H10D 30/00; H10D 62/10; H10D 62/13; H10D 62/83; H10D 64/23; H10D 84/85

(52) U.S. Cl. CPC H10D 84/017; H10D 62/102; H10D 62/121; H10D 62/151; H10D 62/83; H10D 64/254; H10D 64/256; H10D 30/502; H10D 84/851; H10D 84/856

(57) ABSTRACT

A method includes forming a source/drain region, forming a contact etch stop layer over the source/drain region, forming an inter-layer dielectric over the contact etch stop layer, and performing an etching process to form a contact opening in the inter-layer dielectric and the contact etch stop layer. The source/drain region is exposed to the contact opening. A silicide formation process is performed to form a silicide region on a surface of the source/drain region. An etching process is performed to remove a metal that is deposited on dielectric regions, wherein the dielectric regions are exposed during the first silicide formation process. A contact plug is formed in the contact opening.

### PRIORITY CLAIM AND CROSS-REFERENCE

This application claims the benefit of the following provisionally filed U.S. Patent application: Application No. 63/711,958, filed on Oct. 25, 2024, and entitled “METHOD FOR MANUFACTURING SEMICONDUCTOR DEVICE,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B through FIGS. 9A and 9B are views of intermediate stages in the formation of CFETs and silicide regions in accordance with some embodiments.

FIGS. 10A and 10B through FIGS. 13A and 13B are views of intermediate stages in the formation of CFETs and silicide regions in accordance with some embodiments.

FIGS. 14A and 14B through FIGS. 19A and 19B are views of intermediate stages in the formation of CFETs and silicide regions in accordance with some embodiments.

FIGS. 20 through 23 are views of intermediate stages in the formation of CFETs and silicide regions in accordance with some embodiments.

FIG. 24 illustrates a flow chart for forming CFETs and silicide regions in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs), silicide regions, and the method of forming the same are provided. In accordance with some embodiments of the present disclosure, the silicide regions are formed with metal being deposited, and at the same time reacting with epitaxy semiconductor layers to form silicide regions. An etching process may be performed to remove the metals undesirably deposited on the surfaces of dielectric regions. A reduction process may be performed to reduce the metal oxide formed due to vacuum break back to elemental metal.

It is appreciated that while the CFETs include Gate-All-Around (GAA) transistors (such as nanostructure-FETs) as examples, the concept of the present disclosure can also be applied to the formation of silicide regions for other types of transistors such as planar transistors, Fin Field-Effect Transistors (FinFETs), and the like. Throughout the description, the terms “FET” and “transistor” are used interchangeably.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

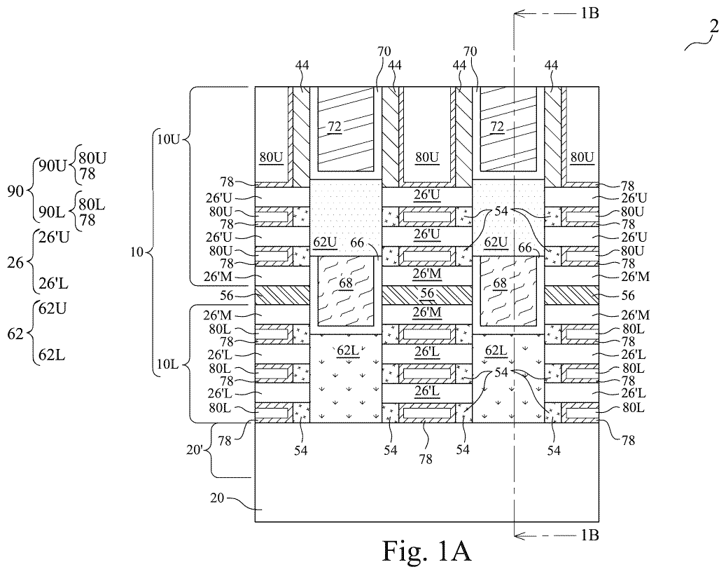

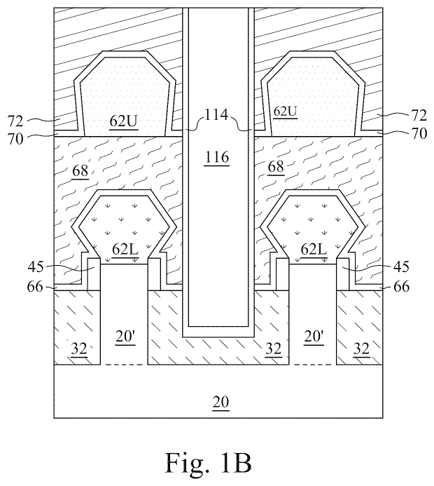

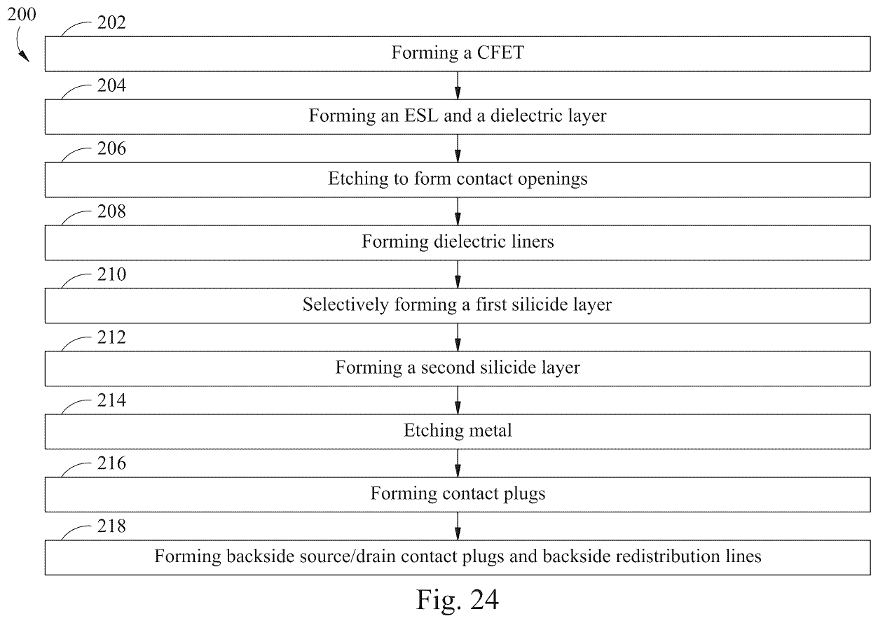

FIGS. 1A and 1B through FIGS. 9A and 9B illustrate the cross-sectional views of intermediate stages in the formation of CFETs and silicide regions in accordance with some embodiments of the present disclosure. The corresponding processes are also reflected schematically in the process flow shown in FIG. 24.

FIG. 1A illustrates the formation of an example CFET 10 (including FETs (transistors) 10U and 10L) in accordance with some embodiments. The respective process is illustrated as process 202 in the process flow 200 as shown in FIG. 24. CFET 10 may include a lower nanostructure-FET 10L of a first device type (e.g., n-type/p-type) and an upper nanostructure-FET 10U of a second device type (e.g., p-type/n-type) that is opposite the first device type.

The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

As shown in FIG. 1A, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multilayered or gradient substrate may also be used. In some embodiments, the semiconductor material of the substrate 20 may include silicon, germanium, carbon-doped silicon, a III-V compound semiconductor, or the like, or combinations thereof.

In the illustrated example, each of the upper FET 10U and lower FET 10L includes two semiconductor layers 26′U and 26′L, respectively, as the channels. It should be appreciated that the upper FET 10U and lower FET 10L may include any number of channel regions such as 1, 2, 3, or more. The portions of the gate stack 90 that are overlying and/or underlying the channel regions 26 form multilayer stacks with the corresponding channel regions 26′U and 26′L.

Gate stacks 90 (including upper gate stacks 90U and lower gate stacks 90L) are formed between semiconductor layers 26. Upper gate stacks 90U includes gate dielectrics 78 and upper gate electrodes 80U. Lower gate stacks 90L includes gate dielectrics 78 and lower gate electrodes 80L. Gate dielectrics 78 encircle (when viewed in side views) the respective semiconductor nanostructures 26. Gate electrodes 80 (including a lower gate electrode 80L and an upper gate electrode 80U) are over the gate dielectrics 78. Dielectric isolation layers 56 are formed to isolate the gate stack 90U of the upper FETs 10U from the gate stack 90L of the lower FETs 10L. Dummy semiconductor layers 26′M may be formed to contact dielectric isolation layers 56.

Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context.

Inner spacers 54, which are dielectric spacers, are formed on the opposing sides of the portions of gate stacks 90, which portions are between semiconductor layers 26. Inner spacers 54 electrically insulate the source/drain regions 62L and 62U from the corresponding parts of gate stacks 90 to prevent and reduce leakage.

Gate spacers 44 are formed over the multilayer stacks and on the sidewalls of gate stacks 90. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as Chemical Vapor Deposition (CVD), Atomic Layer Deposition (ALD), or the like.

Source/drain regions 62L and 62U are formed laterally between the multilayer stacks that comprise channel regions 26 and gate stacks 90. Lower source/drain regions 62L are formed over and contacting a substrate, which includes semiconductor substrate 20. The lower source/drain regions 62L are further in contact with the lower semiconductor nanostructures 26′L and are not in contact with the upper semiconductor nanostructures 26′U.

The lower source/drain regions 62L are epitaxially grown, and have a conductivity type that is suitable for the device type (p-type or n-type) of the lower nanostructure-FETs. When lower source/drain regions 62L are n-type source/drain regions, the respective material may include silicon or carbon-doped silicon, which is doped with an n-type dopant such as phosphorous, arsenic, or the like. When lower source/drain regions 62L are p-type source/drain regions, the respective material may include silicon or silicon germanium, which is doped with a p-type dopant such as boron, indium, or the like. The lower source/drain regions 62L may be in-situ doped, and may be, or may not be, implanted with the corresponding p-type or n-type dopants.

A first contact etch stop layer (CESL) 66 and a first ILD 68 are formed over the lower source/drain regions 62L. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like. The first CESL 66 may be formed of a dielectric material having a high etching selectivity from the etching of the first ILD 68. For example, the first CESL 66 may comprise silicon nitride, silicon oxide, silicon oxynitride, or the like, which may be formed by any suitable deposition process, such as CVD, ALD, or the like.

Upper source/drain regions 62U are formed overlapping the first CESL 66 and the first ILD 68, and overlapping the lower source/drain regions 62L. The materials of upper source/drain regions 62U may be selected from the same candidate group of materials for forming lower source/drain regions 62L, depending on the desired conductivity type of upper source/drain regions 62U.

The conductivity type of the upper source/drain regions 62U may be opposite the conductivity type of the lower source/drain regions 62L. Alternatively stated, the upper source/drain regions 62U may be oppositely doped than the lower source/drain regions 62L. The upper source/drain regions 62U may be in-situ doped, and/or may be implanted, with an n-type or p-type dopant.

A second CESL 70 and a second ILD 72 are formed over the upper source/drain regions 62U. The materials may be similar to, and may be the same as or different from, the materials and the formation methods of the first CESL 66 and first ILD 68, respectively, and are not discussed in detail herein.

FIG. 1B illustrates a cross-sectional view of the structure as shown in FIG. 1A. The illustrated cross-section may be the cross-section 1B-1B as in FIG. 1A. Dielectric isolation regions 32, also sometimes referred to as Shallow Trench Isolation (STI) regions 32, are formed over substrate 20. Semiconductor strips 20′ (also refer to FIG. 1A) are formed between the STI regions 32. Fin spacers 45 may be formed on the sidewalls of the top portions of semiconductor strips 20′. Lower source/drain regions 62L, the first CESL 66, the first ILD 68, the upper source/drain regions 62U, the second CESL 70, and the second ILD 72 are illustrated.

FIG. 1B further illustrates the formation of contact plug 116. In accordance with some embodiments, the formation of contact plug 116 includes etching the second ILD 72, the second CESL 70, the first ILD 68, and the first CESL 66, so that a trench is formed. The trench may extend to an intermediate level between the top surface and the bottom surface of isolation region 32.

Dielectric liner 114 is formed in the trench. In accordance with some embodiments, the formation of dielectric liner 114 includes deposition using a conformal deposition method such as Chemical Vapor Deposition (CVD), Atomic Layer Deposition (ALD), Physical Vapor Deposition (PVD), or the like to form a conformal dielectric layer. In accordance with some embodiments, the material of dielectric liner 114 may include silicon oxide, silicon nitride, a metal oxide of a metal such as Hf, Ti, Al, W, Nb, Re, or the like, a metal nitride of a metal such as Hf, Ti, Al, W, Nb, Re, or the like, or combinations thereof.

Contact plug 116 is then formed. Contact plug 116 may also be referred to as a vertical local interconnect. In accordance with some embodiments, contact plug 116 comprises a metal such as tungsten, molybdenum, ruthenium, iridium, or the like, or alloys thereof. In accordance with some embodiments, contact plug 116 has a single-layer structure, with the entire contact plug 116 formed of a homogeneous material such as aforementioned.

In accordance with alternative embodiments, the formation of contact plug 116 may include depositing a barrier layer, which may comprise titanium, titanium nitride, tantalum, tantalum nitride, or the like. Next, a metallic material is deposited over and in contact with the barrier layer. The metallic material may include tungsten, cobalt, copper, nickel, molybdenum, ruthenium, iridium, or the like, or a combination thereof.

After the deposition of the materials for forming contact plug 116, a planarization process such as a CMP process or a mechanical grinding process is performed to remove excess portions of the deposited material(s), leaving contact plug 116. The contact plug 116 is thus encircled by the dielectric liner 114. The top surfaces of contact plug 116 and dielectric liner 114 are coplanar, and may further be coplanar with the top surface of the second ILD 72 when the second ILD 72 is the top layer in the structure.

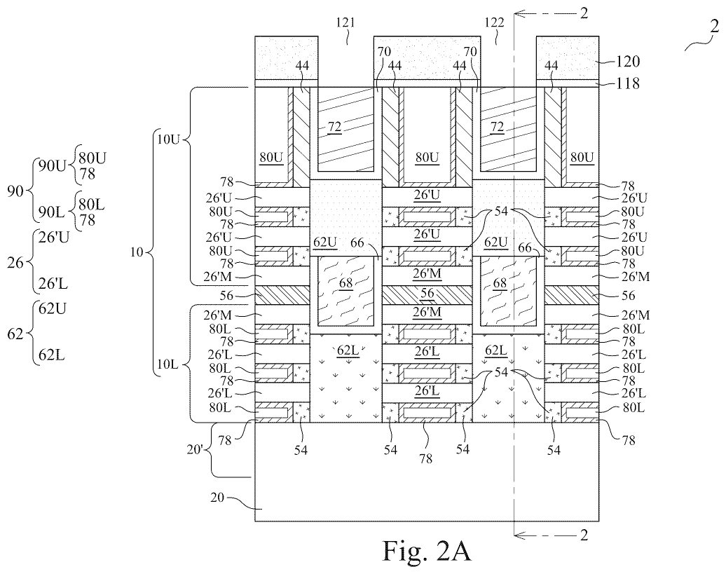

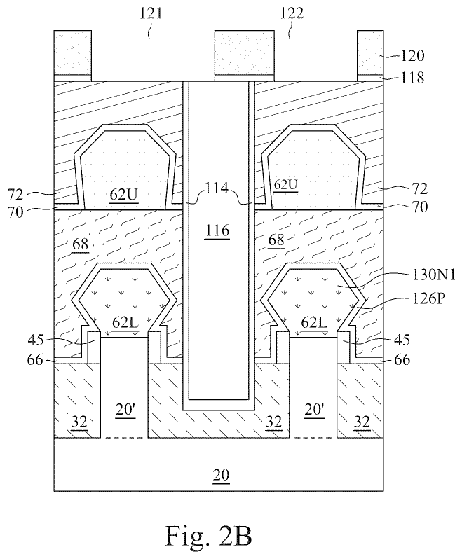

Referring to FIGS. 2A and 2B, etch stop layer 118 and dielectric layer 120 are formed. The respective process is illustrated as process 204 in the process flow 200 as shown in FIG. 24. Etch stop layer 118 may comprise AlN, AlO, SiOC, or the like, or multilayers thereof. Dielectric layer 120 may comprise silicon oxide, silicon nitride, silicon oxynitride, silicon carbide, or the like. Etch stop layer 118 and dielectric layer 120 are patterned through etching to form openings 121 and 122, through which the second ILD 72 and contact plug 116 are exposed.

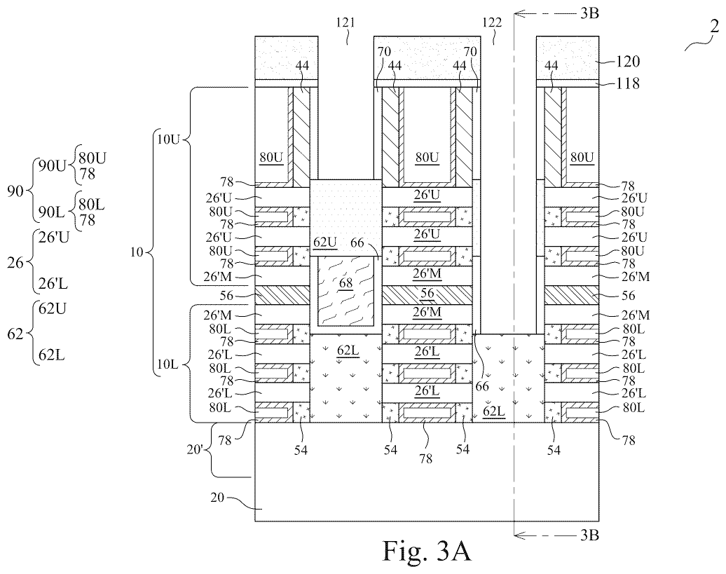

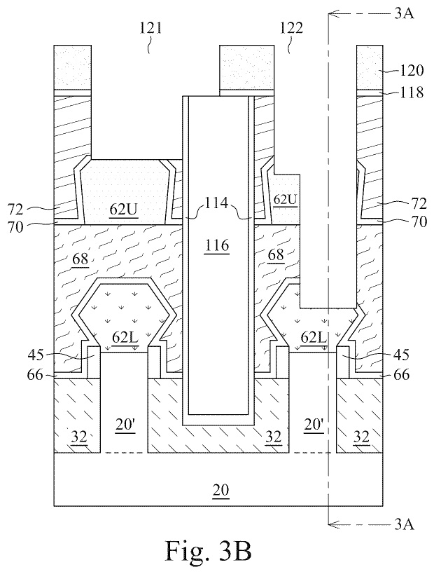

FIGS. 3A and 3B illustrate the cross-sectional views of the further formation of source/drain contact openings 121 and 122 in accordance with some embodiments. The respective process is illustrated as process 206 in the process flow 200 as shown in FIG. 24. The cross-sectional view as shown in FIG. 3A is obtained from the cross-section 3A-3A in FIG. 3B, and the cross-sectional view as shown in FIG. 3B is obtained from the cross-section 3B-3B in FIG. 3A.

Contact openings 121 and 122 are formed through etching processes. In the etching processes, the underlying second ILD 72, second CESL 70, contact plug 116, and dielectric liner 114 are exposed. The second ILD 72 and the second CESL 70 are etched, so that the upper source/drain regions 62U are exposed. On the illustrated right side of the contact plug 116, some parts of the upper source/drain regions 62U are etched-through, followed by the etching of the underlying first ILD 68 and first CESL 66. The etching stops on the top surface of the lower epitaxy source/drain region 62L. Some top surfaces of the upper epitaxy source/drain region 62U may also be exposed. For example, on the left side of the illustrated contact plug 116, the contact opening 121 stops on the top surface of one of upper source/drain regions 62U.

It is appreciated that the etching may be performed through one etching mask or more etching masks to achieve the desirable pattern. For example, one etching mask may be used to etch-through the upper source/drain region 62U, with the etching stopping on the lower source/drain region 62L. Another etching mask may be used to etch some portions of the second ILD 72 and second CESL 70 so that the top surfaces of some portions of the upper source/drain region 62U are exposed.

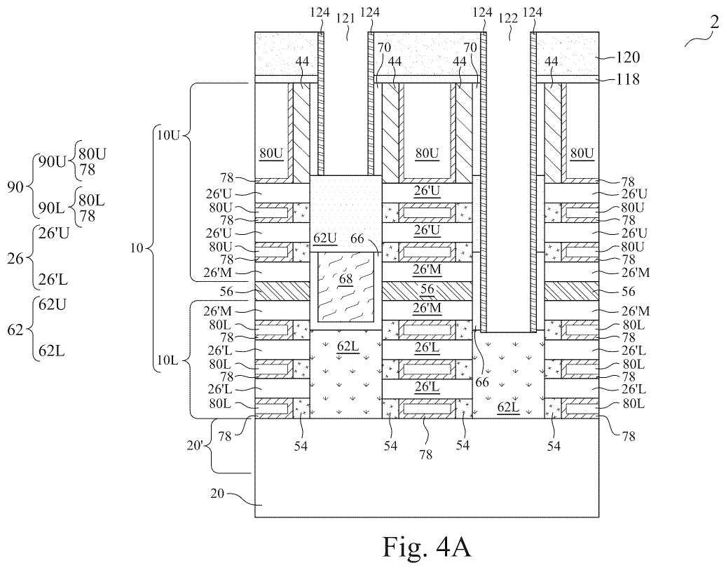

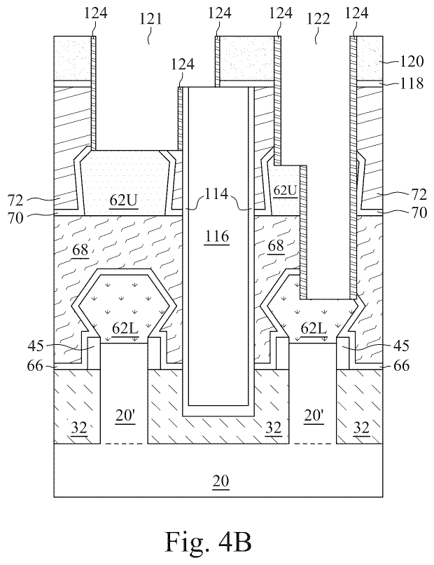

Referring to FIGS. 4A and 4B, dielectric liners 124 are formed. The respective process is illustrated as process 208 in the process flow 200 as shown in FIG. 24. In accordance with some embodiments, the formation of dielectric liners 124 includes depositing a conformal dielectric layer through a conformal deposition process, for example, through ALD, CVD, PVD, or the like. An anisotropic etching process is then performed to remove the horizontal portion of the conformal layer, leaving the vertical portions as the dielectric liners 124.

The material of the dielectric liners 124 may be selected from the same group of candidate materials for forming dielectric liner 114, and may be the same as or different from the material of dielectric liner 114. For example, dielectric liners 124 may be formed of and/or comprise silicon nitride.

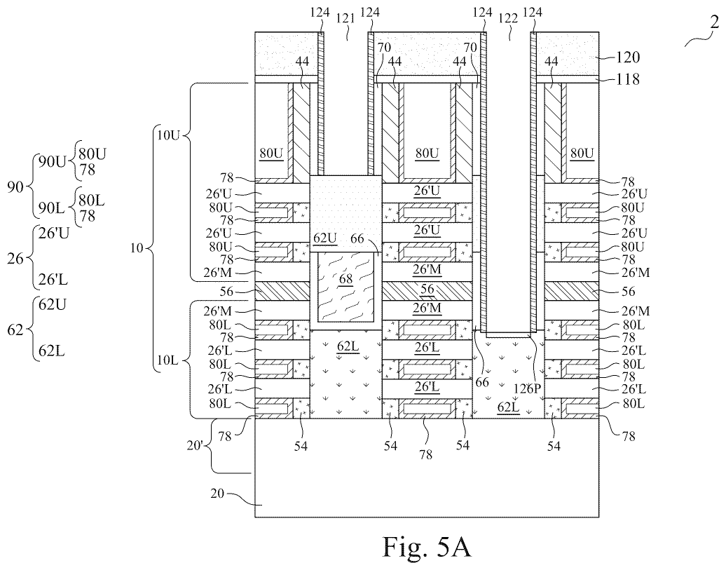

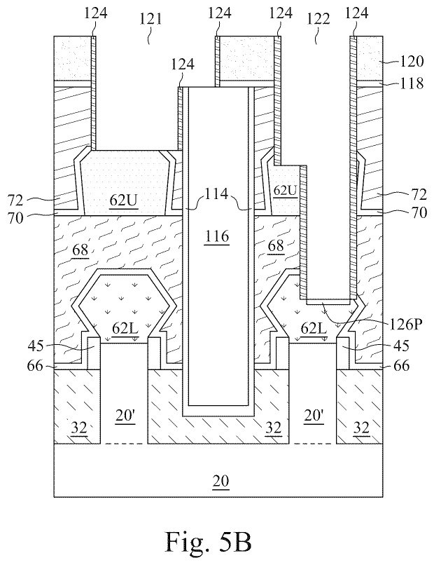

Referring to FIGS. 5A and 5B, silicide regions 126P are formed selectively. The respective process is illustrated as process 210 in the process flow 200 as shown in FIG. 24. In accordance with some embodiments, the formation of silicide region 126P may include conducting certain precursors that are capable of reacting with germanium but not silicon into the respective reaction chamber. As a result, p-type silicide regions 126P are selectively formed on germanium or SiGe, while no silicide region is formed on the exposed surface of upper source/drain regions 62U (which may comprise Si but free from Ge) and the exposed surfaces of dielectrics. In accordance with some embodiment, the precursor that may result in the selective formation of silicide region 126P may comprise M(DAD)ₓ (wherein M represents a metal, and value x is an integer). For example, the precursor may comprise Bis(1,4-di-t-butyl-1,3-diazabutadienyl)nickel(II) (Ni(DAD)₂), MeCpMMex (such as Trimethyl(methylcyclopentadienyl)platinum(IV)), wherein the second M represents metal, and the x represent a number, or the like. In addition, an etching gas such as HCl may be added into the precursor, so that the silicide does not grow on the exposed dielectric materials.

Throughout the description, silicides include the silicides with high work functions (which silicides are referred to as p-silicides), silicides with low work functions (which silicides are referred to as n-silicides), and the silicides (mid-work-function silicides) with mid-work-functions between the work functions of the p-silicides and the work functions of the n-silicides. For example, the mid-work-function silicides may have work functions in the range between about 4.2 eV and about 4.4 eV. The p-silicides may have work functions greater than about 4.4 eV. The n-silicides may have work functions lower than about 4.2 eV.

In accordance with some embodiments, the silicides with work functions close to that of titanium silicide may be considered as mid-work-function silicides, and the silicides with work functions greater than that of Ti silicide (metal) are p-silicides. Conversely, the silicides with a work function lower than that of Ti silicide (metal) are n-silicides. The mid-work-function silicides may include VSi, ZnSi, NbSi, AlSi, and the like.

In accordance with some embodiments, depending on the precursor that is used, p-type silicide regions 126P may include (in addition to Ge or SiGe) a metal selected from molybdenum (Mo), nickel (Ni), ruthenium (Ru), iridium (Ir), palladium (Pd), platinum (Pt), tungsten (W), cobalt (Co), chromium (Cr), osmium (Os), Rhenium (Re), rhodium (Rh), iron (Fe), manganese (Mn), vanadium (V), tantalum (Ta), and combinations thereof.

To incur the silicidation process, gases such as Ar, H₂, and/or the like are conducted along with the precursor gas(es). Plasma (and RF power) is also turned on. In addition, wafer 2 is also heated, for example, to a temperature in the range between about 300° C. and about 600° C. The metal in the precursor is deposited on lower source/drain regions 62L, and reacts with the exposed surface layers of lower source/drain regions 62L to form p-type silicide regions 126P.

In accordance with some embodiments, after the silicidation process, no additional anneal process is performed for the formation of p-type silicide regions 126P. Also, the metal in the precursor is not deposited on the surfaces of dielectric materials such as dielectric liners 124 due to the high selectivity of the selective deposition process.

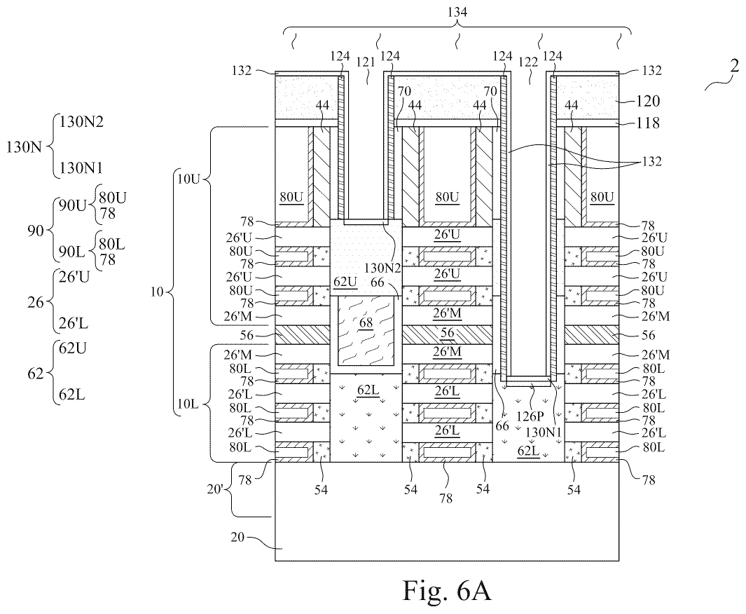

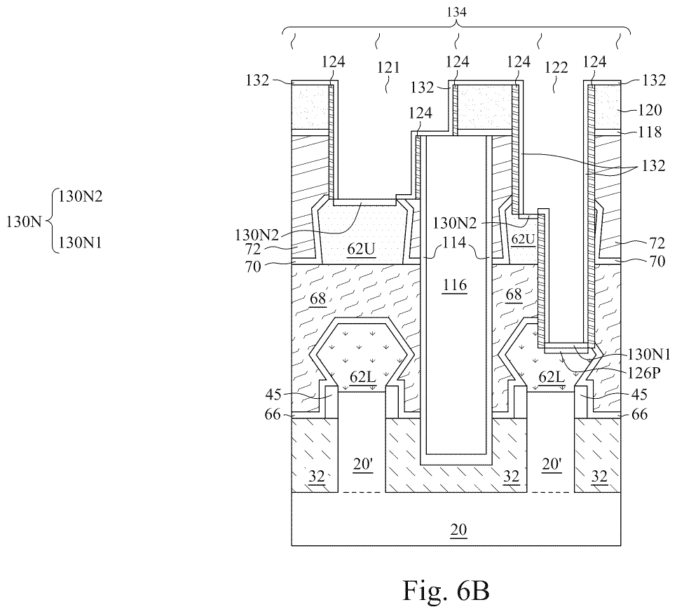

FIGS. 6A and 6B illustrate the formation of n-type silicide regions 130N (including N-type silicide regions 130N1 and 130N2). The respective process is illustrated as process 212 in the process flow 200 as shown in FIG. 24. In accordance with some embodiments, the formation process may include conducting a precursor comprising an n-type metal into the corresponding reaction chamber.

The n-type metal may comprise Zr, Sb, Ce, Sc, Y, Ub, Er, or the like, or combinations thereof. Gases such as Ar, H₂, or the like may be conducted. Plasma is also turned on. In addition, wafer 2 is also heated, for example, to a temperature in the range between about 300° C. and about 600° C. N-type silicide regions 130N may be formed in-situ with the formation of p-type silicide regions 126P, without vacuum break in between.

In the deposition processes, the silicon and Ge in lower source/drain regions 62L diffuses upwardly through p-type silicide regions 126P, and react with the metal deposited from the precursor to form the n-type silicide regions 130N1, which is over the p-type silicide regions 126P. Over upper source/drain regions 62U, the silicon reacts with the metal deposited from the precursor to form the n-type silicide regions 130N2. In accordance with some embodiments, after the silicidation process, no additional anneal process is performed for the formation of n-type silicide regions 130N. N-type silicide regions 130N1 and 130N2 are collectively referred to as n-type silicide regions 130N.

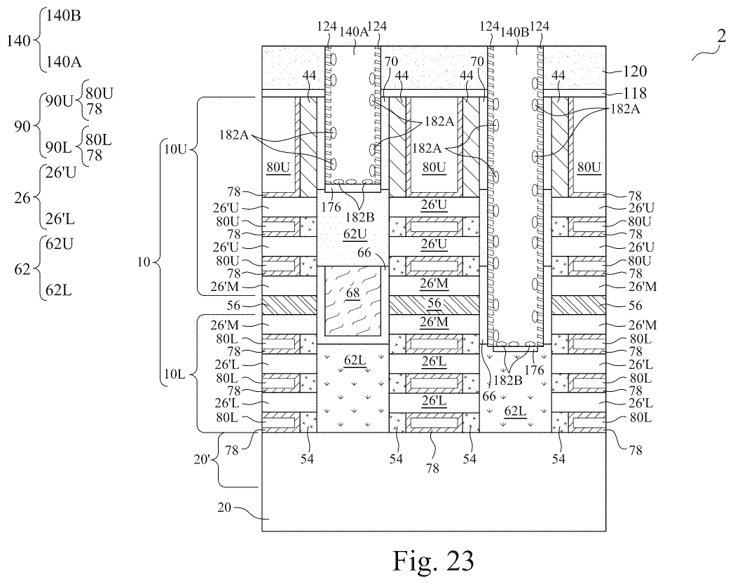

In the silicidation process, due to the low selectivity in the deposition of the n-type metals, a thin metal layer 132 is deposited on the surface of dielectric layers at the same time the silicidation process is performed. Accordingly, metal layer 132 comprises the same metal as n-type silicide regions 130N. The metal in metal layer 132 may comprise an elemental metal(s), which include metal atoms, rather than metal compounds. It is appreciated that although metal layer 132 is illustrated as a continuous layer, metal layer 132 may also be a discontinuous layer that includes a plurality of discrete metal islands. The surfaces of the underlying dielectric regions (such as dielectric liners 124) may be exposed through the discrete metal islands. Example discrete metal islands may be represented by the discrete metal regions 182A and 182B as shown in FIG. 23.

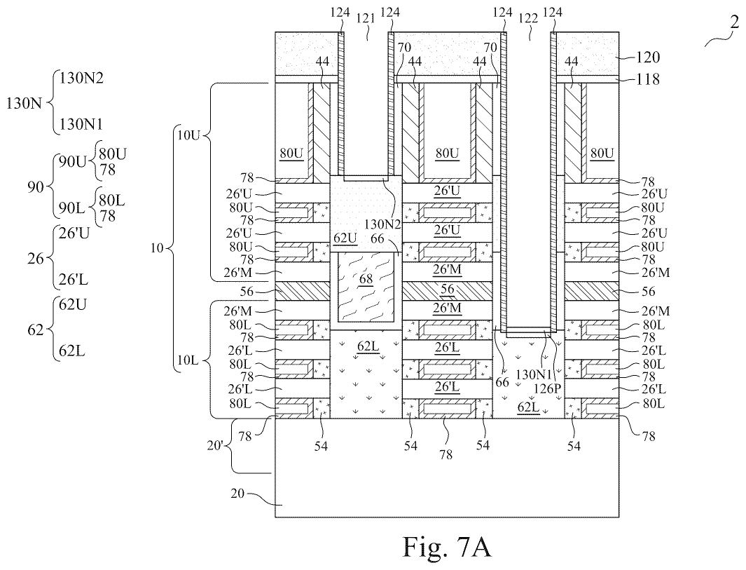

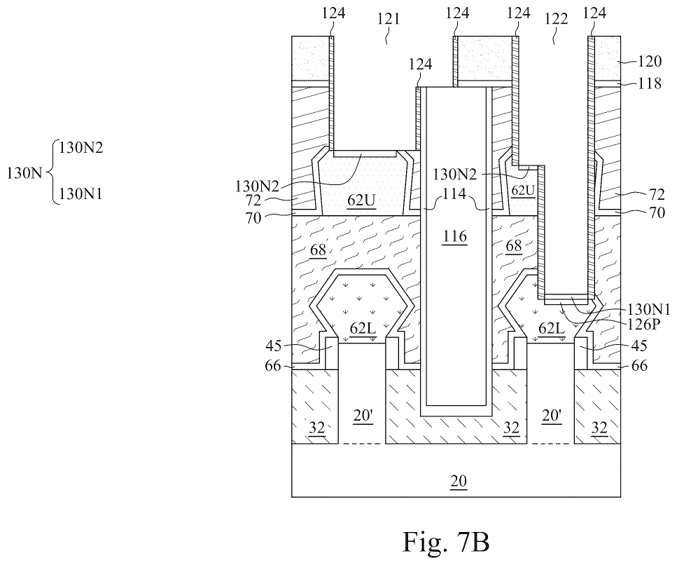

Further referring to FIGS. 6A and 6B, an etching process 134 is performed to selectively etch the metal layer 132, while silicide regions 132N (including silicide regions 132N1 and 132N2) and the exposed dielectric regions such as dielectric liners 124 are not etched. The respective process is illustrated as process 214 in the process flow 200 as shown in FIG. 24. In accordance with some embodiments, the selective etching process is performed through a soaking process using an etching gas comprising a metal halide(s). The result structure is shown in FIGS. 7A and 7B.

The metal halide may be selected from titanium chloride (TiCl₄), nickel halide (e.g., nickel fluoride (NiF₂), nickel dichloride (NiCl₂), nickel bromide (NiBr₂), nickel iodide (NiI₂), Molybdenum halide (e.g., Molybdenum fluoride (MoF₄ and/or MoF₅), Molybdenum chloride (MoCl₂, MoCl₃, MoCl₄, MoCl₅, MoCl₆, Molybdenum bromide (MoBr2, MoBr4), and the like), platinum halide (e.g., platinum fluoride (PtF₂, PtF₃), platinum chloride (PtCl₂, PtCl₄), platinum bromide (PtBr₂), platinum iodide (PtI₂, PtI₄, and the like), palladium halide (e.g., palladium fluoride (PdF₂, PdF₃, PdF₄, PdF₆), palladium dichloride (PdCl₂, PdCl₃, PdCl₄), palladium bromide (PdBr₂, PdBr₄), palladium iodide (PdI₂, PdI₄), cobalt halide (e.g., cobalt fluoride (CoF₂, CoF₃), cobalt chloride (CoCl₂, CoCl₃), cobalt iodide (CoI₂), titanium halide (e.g., titanium fluoride (TiF₃, TiF₄), titanium chloride (TiCl₂, TiCl₃, TiCl₄), titanium bromide (TiBr₂, TiBr₃, TiBr₄), titanium iodide (TiI₂, TiI₄), and the like).

The metal halide may also be selected erbium halide (e.g., erbium fluoride (ErF₂, ErF₃), erbium chloride (ErCl₃), erbium bromide (ErBr₃), erbium iodide (ErI₃), and the like), zirconium halide (e.g., zirconium fluoride (ZrF₃, ZrF₄), zirconium chloride (ZrCl₂, ZrCl₃, ZrCl₄), zirconium bromide (ZrBr₂, ZrBr₃, ZrBr₄), zirconium iodide (ZrI₂, ZrI₄), and the like), hafnium halide (hafnium fluoride (HfF₃, HfF₄), hafnium chloride (HfCl₂, HfCl₃, HfCl₄), hafnium bromide (HfBr₂, HfBr₃, HFBr₄), hafnium iodide (HfI2, HfI4), and the like), tungsten halide (e.g., tungsten fluoride (WF₄, WF₆), tungsten chloride (WCl₂, WCl₃, WCl₄, WCl₅, WCl₆), tungsten bromide (WBr₂, WBr₅, WBr₆), ruthenium halide (e.g., ruthenium chloride (RuCl₂, RuCl₃, RuCl₄), ruthenium bromide (RuBr₃, RuBr₄), ruthenium fluoride (RuF₃, RuF₄), ruthenium iodide (RuI₃), and the like), or combinations thereof.

The etching gas may (or may not) also include a hydrogen halide such as HF, HBr, HCl, HI, or the like, or combinations thereof. During the etching process, no plasma is generated. There may not be RF power applied, or an RF power is applied but not high enough to generate plasma. Also, there may not be Ar introduced, and there may not be H₂ introduced.

In accordance with some embodiments, the etching may be performed at a wafer temperature in the range between about 20 and about 600° C.

As a comparison, in accordance with some embodiments, in an entire period of time after the formation of silicide regions 126P and before the formation of n-type silicide regions 130N (as shown in FIGS. 6A and 6B), no etching process using the metal halide is performed to etch metal. This is partially due to that the selective formation of silicide regions 126P has a high selectivity, so that no metal layer is formed on dielectric materials and upper source/drain regions 62U.

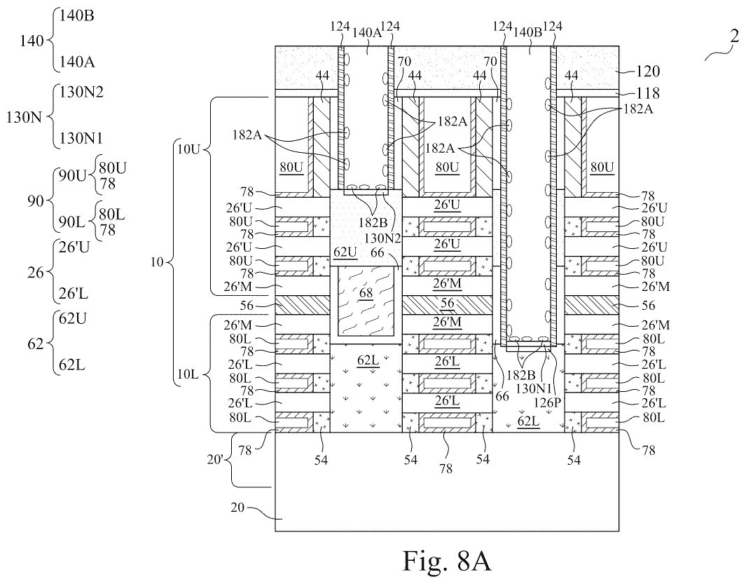

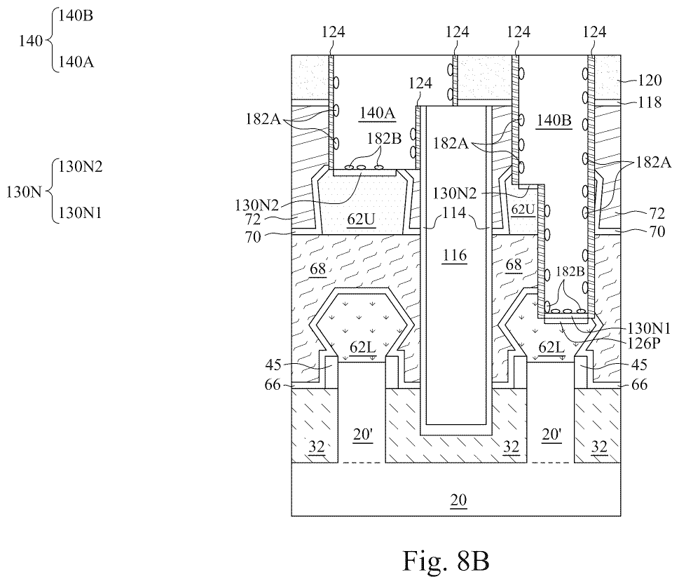

Next, referring to FIGS. 8A and 8B, contact plugs 140A and 140B are formed, which are individually and collectively referred to as contact plugs 140. The respective process is illustrated as process 216 in the process flow 200 as shown in FIG. 24. Contact plugs 140A and 140B may be referred to as source/drain contact plugs, and contact plug 140A may be referred to as an upper source/drain contact plug. In accordance with some embodiments, contact plugs 140A and 140B comprise a metal such as tungsten, molybdenum, ruthenium, iridium, or the like, or alloys thereof. In accordance with some embodiments, contact plugs 140A and 140B have a single-layer structure, with the entire contact plugs 140A and 140B being formed of a homogeneous material such as aforementioned.

In accordance with alternative embodiments, the formation of contact plugs 140A and 140B may include forming a barrier layer, which may comprise titanium, titanium nitride, tantalum, tantalum nitride, or the like. Next, a metallic material is deposited over and in contact with the barrier layer. The metallic material may include tungsten, cobalt, copper, nickel, molybdenum, ruthenium, iridium, or the like, or a combination thereof.

Further referring to FIGS. 8A and 8B, after the deposition of the material for forming contact plug 116, a planarization process such as a CMP process or a mechanical grinding process is performed to remove excess portions of the deposited material(s), leaving contact plugs 140A and 140B. The contact plugs 140A and 140B are thus encircled by the dielectric liners 124. The top surfaces of contact plugs 140A and 140B and dielectric liners 124 are thus coplanar, and may further be coplanar with the top surface of the dielectric layer 120.

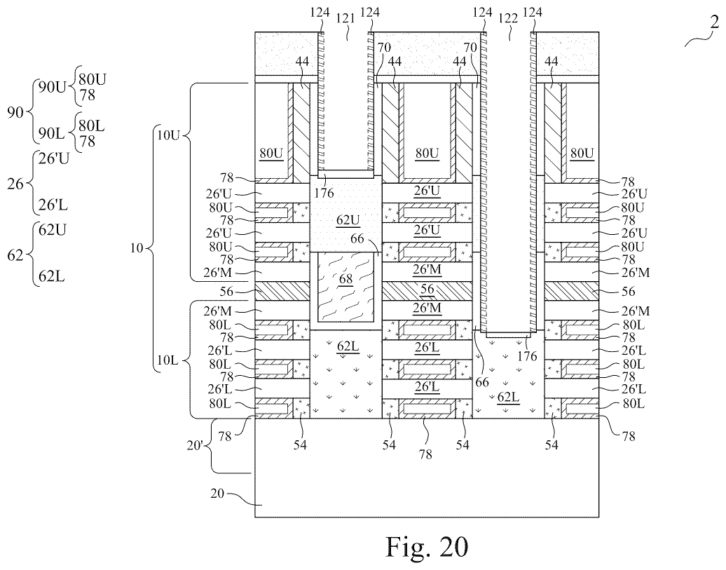

In accordance with some embodiments, as discussed above, metal layer 132 is removed in the etching process 134 (FIGS. 6A and 6B). In accordance with alternative embodiments, etching process 134 is not performed, and metal layer 132 is not removed at this stage. At a time after the structure shown in FIGS. 7A and 7B are formed and before the formation of contact plugs 140A and 140B, a vacuum break may be performed, causing the metal layer 132 to be oxidized. Accordingly, the process as shown in FIGS. 20 through 23 may be performed to reduce the oxidized metal layer 132 back to metal. Discrete metal islands 182A and 182B are schematically illustrated to represent the elemental metal layer 132 in accordance with these embodiments when metal layer 132 is not etched. The discrete metal islands 182A and 182B comprise the same metal as in the underlying n-type silicide layers 130N.

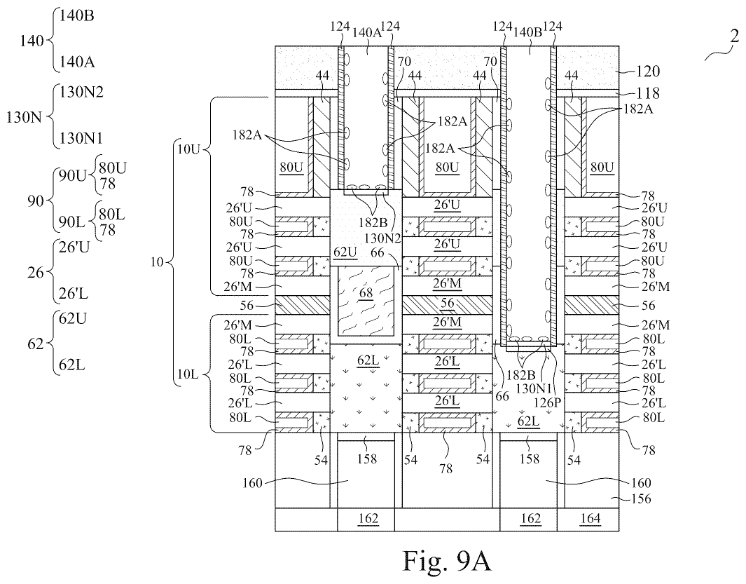

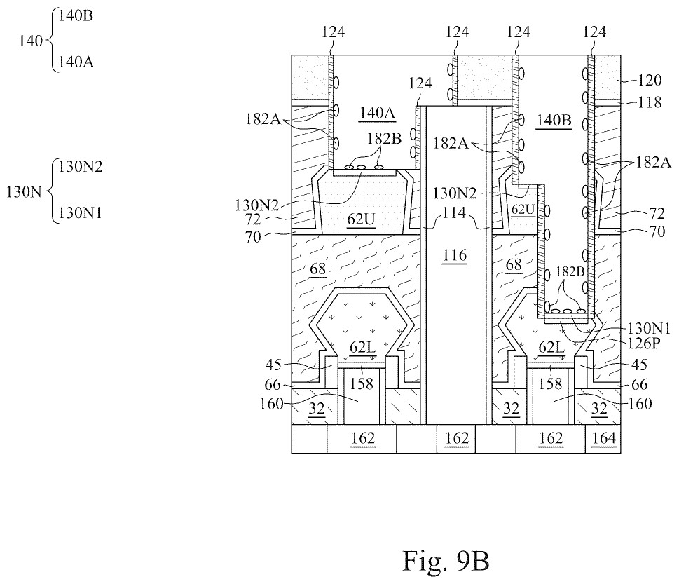

FIGS. 9A and 9B further illustrate the formation of backside source/drain contact plugs 160, which are electrically connected to lower source/drain regions 62L, and the formation of backside redistribution lines. The respective process is illustrated as process 218 in the process flow 200 as shown in FIG. 24. In accordance with some embodiments, substrate 20 (FIGS. 8A and 8B) is removed, for example, through a CMP process and/or an etching process(es). A dielectric substrate 156 (FIG. 9A) may be formed.

Semiconductor strips 20′ (FIGS. 8A and 8B) are etched to form backside openings, through which the bottoms of lower source/drain regions 62L are exposed. Silicide regions 158 are formed underlying and contacting the bottom surfaces of lower source/drain regions 62L. The materials and the formation processes of silicide regions 158 may be essentially the same as that of silicide regions 126P and/or 130N, and are not repeated herein. For example, silicide regions 158 may include p-type silicide regions same as the p-type silicide regions 126P, and may or may not include an n-type silicide region same as the n-type silicide regions 130N.

Backside contact plugs 160 are formed to fill the remaining backside contact openings. Backside contact plugs 160 are in contact with silicide regions 158. Backside contact plugs 160 may be formed of a homogeneous metallic material, which may comprise tungsten, cobalt, ruthenium, or the like. Alternatively, the formation of backside contact plugs 160 may include forming a barrier layer, which may comprise titanium, titanium nitride, tantalum, tantalum nitride, or the like, and the homogeneous metallic material on the barrier layer. A planarization process such as a CMP process or a mechanical grinding process is then performed to remove excess portions of the deposited materials, leaving backside contact plugs 160.

Dielectric layer 164 is then deposited. Backside redistribution lines 162 (conductive features 162) are formed on the backside of CFETs, and are formed in dielectric layer 164. Backside redistribution lines 162 are electrically connected to contact plug 116, and to lower source/drain region 62L.

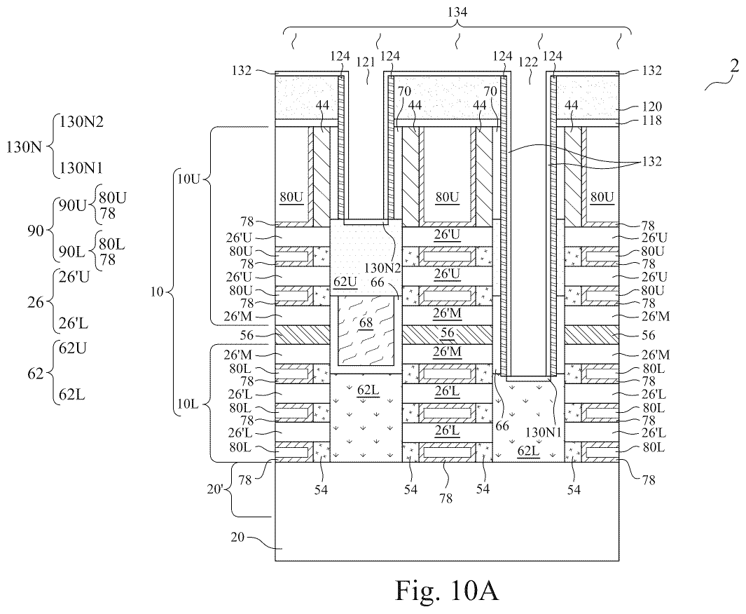

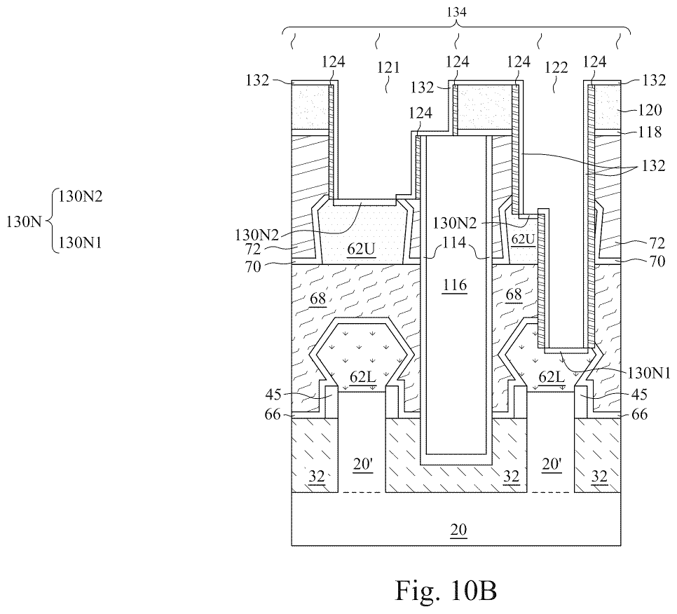

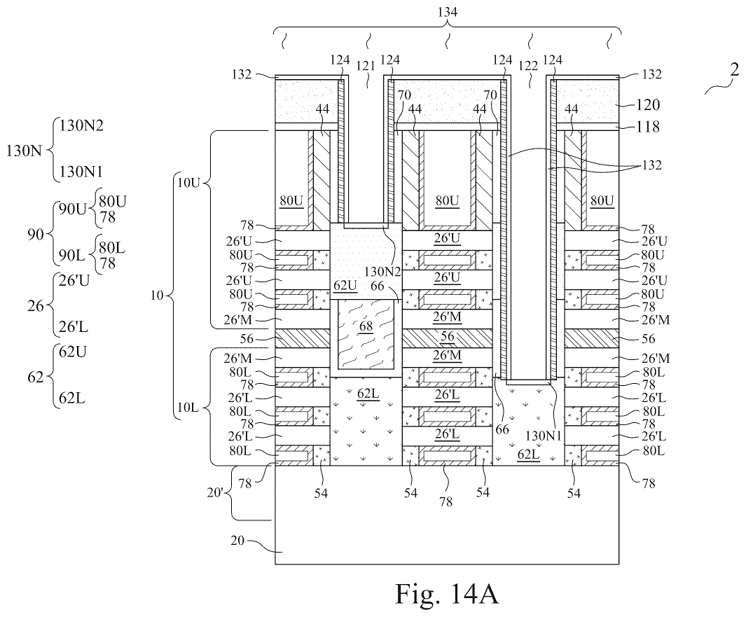

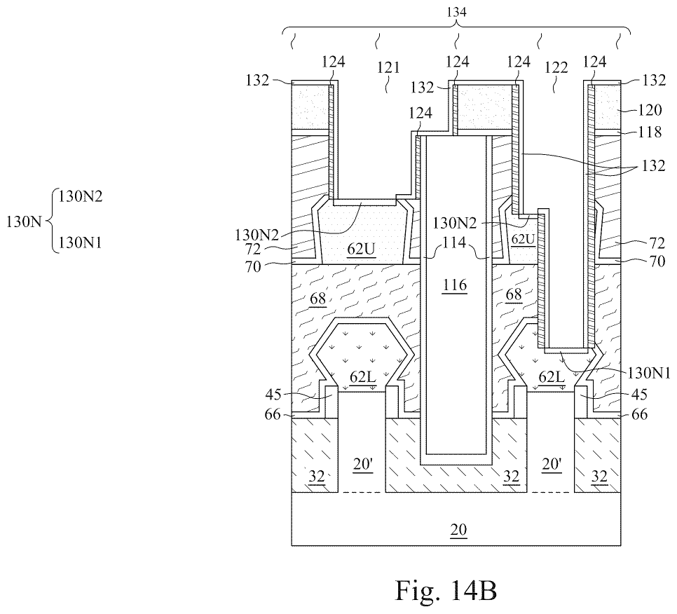

FIGS. 10A and 10B through FIGS. 13A and 13B illustrate the cross-sectional views of intermediate stages in the formation of a CFET in accordance with some embodiments of the present disclosure. In accordance with these embodiments, n-type silicide regions are formed on and in contact with both of lower source/drain regions 62L and upper source/drain regions 62U. Unless specified otherwise, the materials, the structures, and the formation processes of the components in these embodiments (and the embodiments in FIGS. 14A and 14B through FIGS. 19A and 19B) are essentially the same as the like components denoted by like reference numerals in the preceding embodiments. The details regarding the materials, the structures, and the formation processes provided in each of the embodiments throughout the description may be applied to any other embodiment whenever applicable.

The initial steps of these embodiments are essentially the same as shown in FIGS. 1A and 1B through FIGS. 4A and 4B. Next, as shown in FIGS. 10A and 10B, silicide regions 130N (including 130N1 and 130N2) are formed. The materials, the structures, and the formation methods of silicide regions 130N1 and 130N2 may be essentially the same as shown in FIGS. 6A and 6B, and are not repeated herein. N-type silicide regions 130N1 and 130N2 are in physical contact with the underlying lower source/drain regions 62L and 62U, respectively.

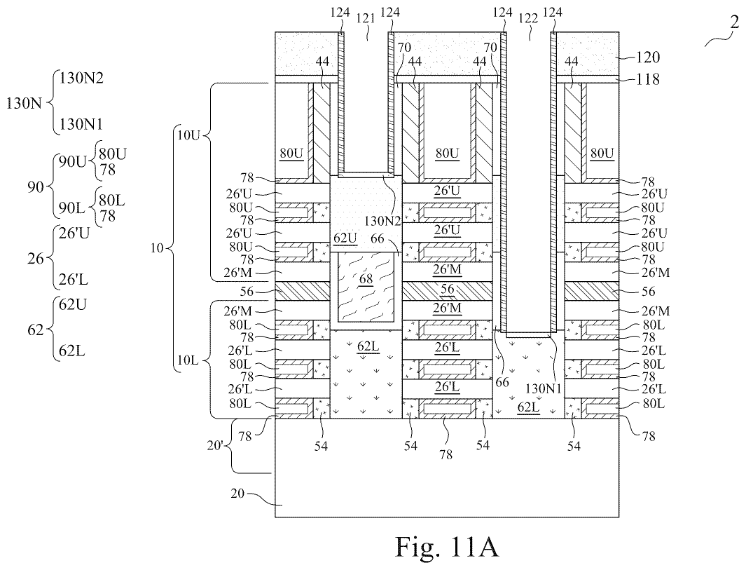

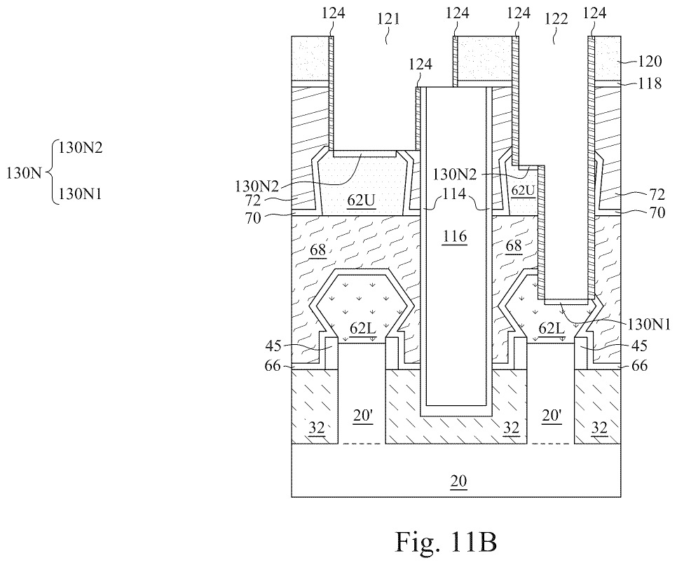

During the formation of n-type silicide regions 130N1 and 130N2, metal layer 132 may be simultaneous formed on the exposed dielectric regions due to the low selectivity in the deposition of the n-type metals. In accordance with some embodiments, the metal layer 132 is removed through etching process 134, which may be essentially the same as the etching process 134 as discussed referring to FIGS. 6A and 6B. The metal layer 132 is thus removed, and the resulting structure is shown as in FIGS. 11A and 11B.

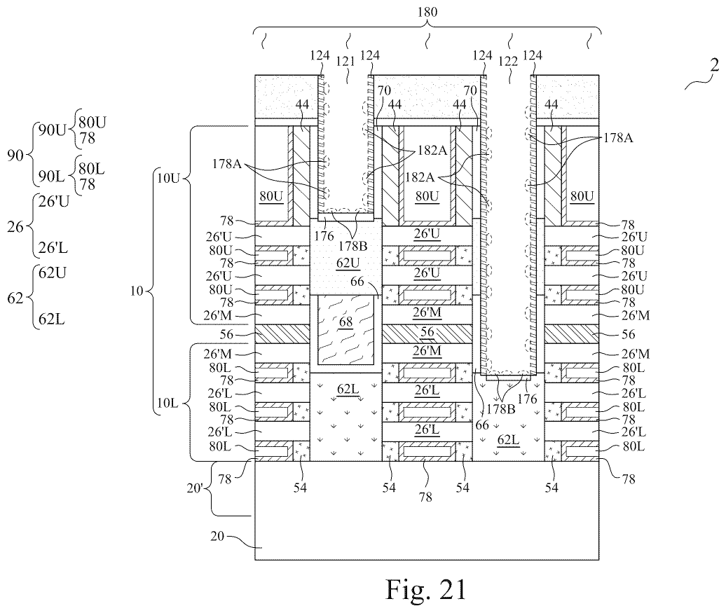

In accordance with alternative embodiments, the metal layer 132 is not removed, and a subsequent vacuum break process may result in the oxidization of the metal layer 132 and thus the formation of metal oxides. The processes as shown in FIGS. 21 through 24 may then be performed to reduce the metal oxide back to elemental metal.

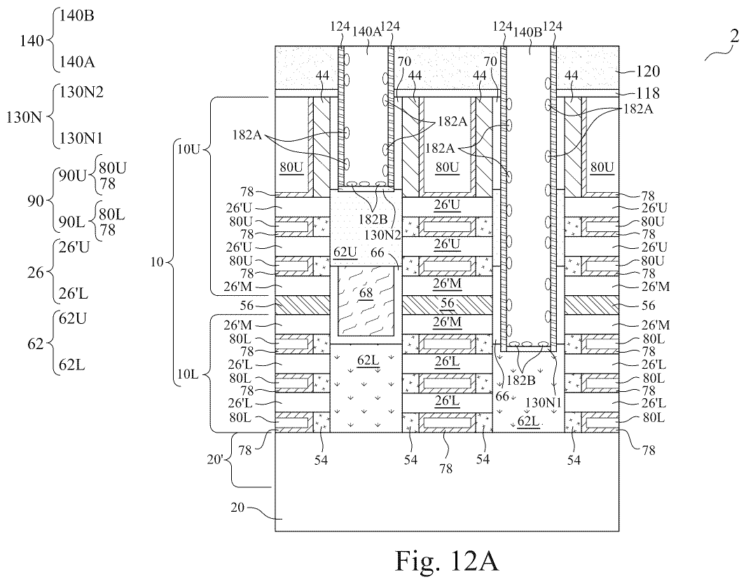

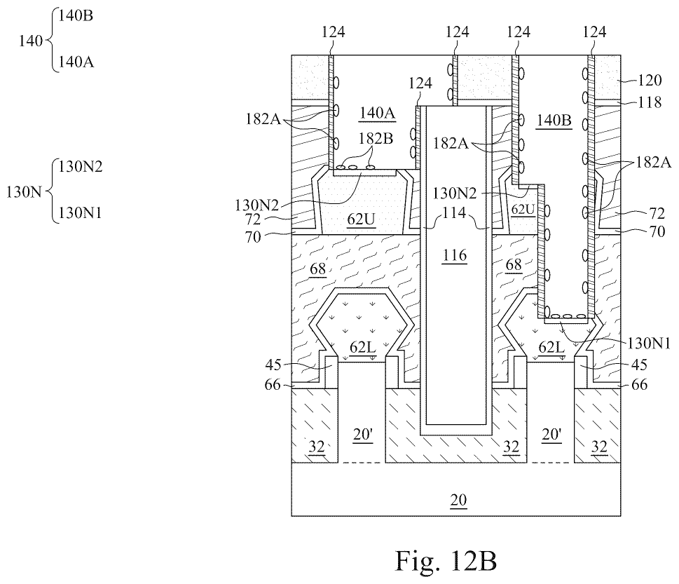

FIGS. 12A and 12B illustrate the formation of contact plugs 140A and 140B. The formation process may be essentially the same as that in FIGS. 8A and 8B. The details are thus not repeated herein. In accordance with some embodiments, when the processes as shown in FIGS. 21-24 are performed, metal islands 182A and 182B (which may be discrete islands or a continuous metal layer) comprising elemental metal may exist at the edges and the bottoms of contact plugs 140A and 140B. The metal in the metal islands 182A and 182B may be the same metal used for forming silicide regions 130N1 and 130N2. In accordance with alternative embodiments, when the metal layer 132 is removed by etching process 134, the metal islands 182A and 182B will not exist.

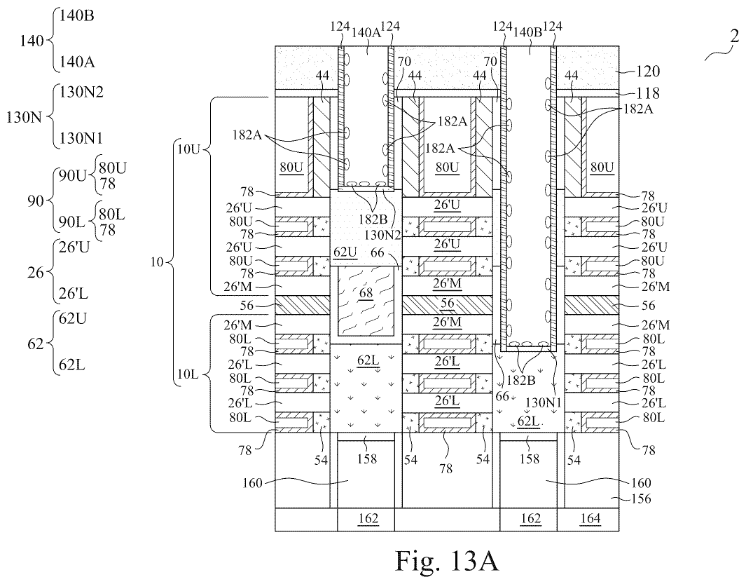

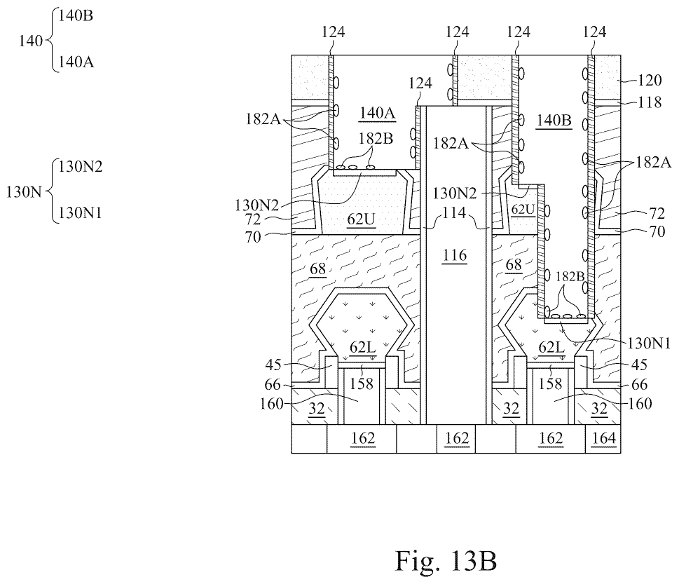

FIGS. 13A and 13B illustrate the formation of backside structures for connecting to the lower source/drain regions 62L from the backside of wafer 2. The materials, the structures, and formation processes may be essentially the same as discussed referring to FIGS. 9A and 9B, and are not repeated herein.

FIGS. 14A and 14B through FIGS. 19A and 19B illustrate the cross-sectional views of intermediate stages in the formation of CFETs and silicide regions in accordance with some embodiments of the present disclosure. In accordance with these embodiments, n-type silicide regions and titanium silicide (TiSi) layers are formed on both of lower source/drain regions 62L and upper source/drain regions 62U.

Referring to FIGS. 14A and 14B, n-type silicide regions 130N1 and 130N2 are formed. The materials, the structures, and the formation process are essentially the same as that discussed referring to FIGS. 6A and 6B, and are not repeated herein. N-type silicide regions 130N1 and 130N2 are in physical contact with the underlying lower source/drain regions 62L and 62U, respectively.

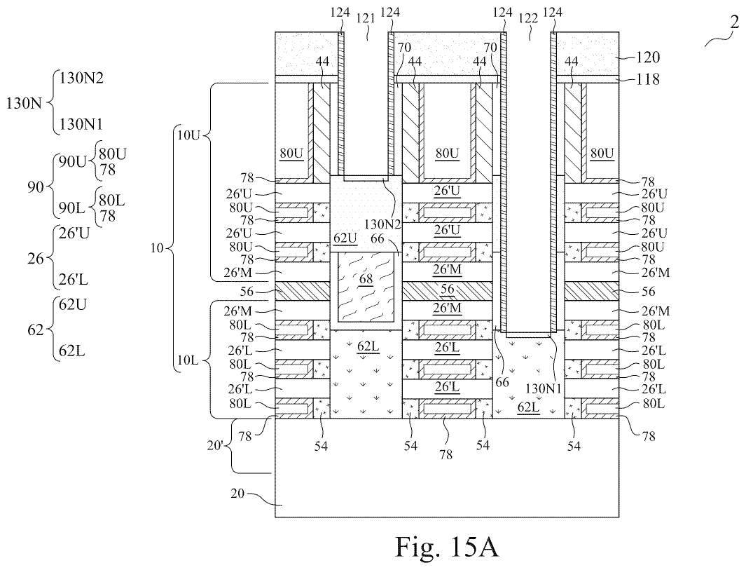

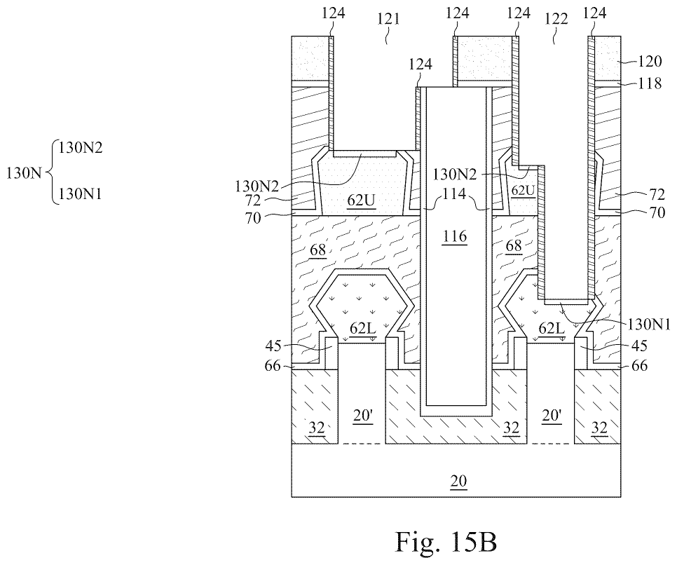

During the formation of n-type silicide regions 130N1 and 130N2, metal layer 132 is also formed on the exposed dielectric regions. In accordance with some embodiments, the metal layer 132 is removed through etching process 134, which may be essentially the same as that discussed referring to FIGS. 6A and 6B. The metal layer 132 is thus removed, and the resulting structure is shown as in FIGS. 15A and 15B.

In accordance with alternative embodiments, the metal layer 132 is not removed, and a subsequent vacuum break process may result in the formation of metal oxides. The processes as shown in FIGS. 20 through 23 may then be performed to reduce the metal oxide back to elemental metal.

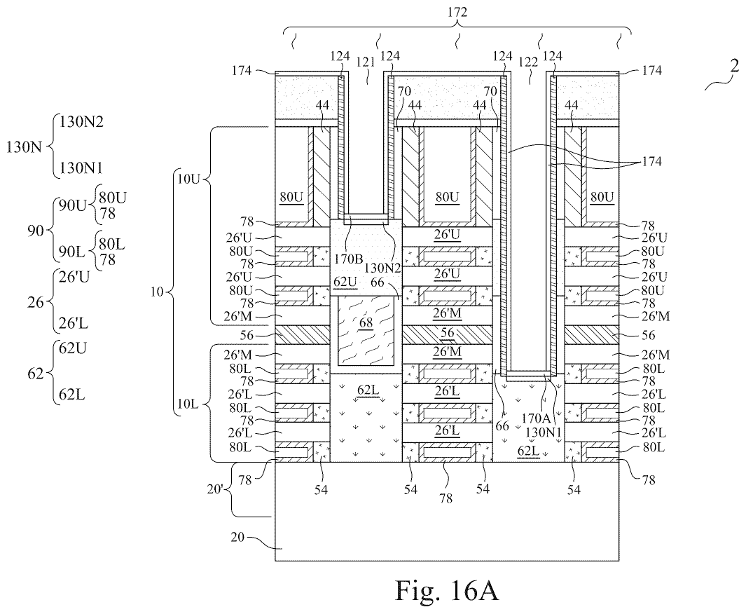

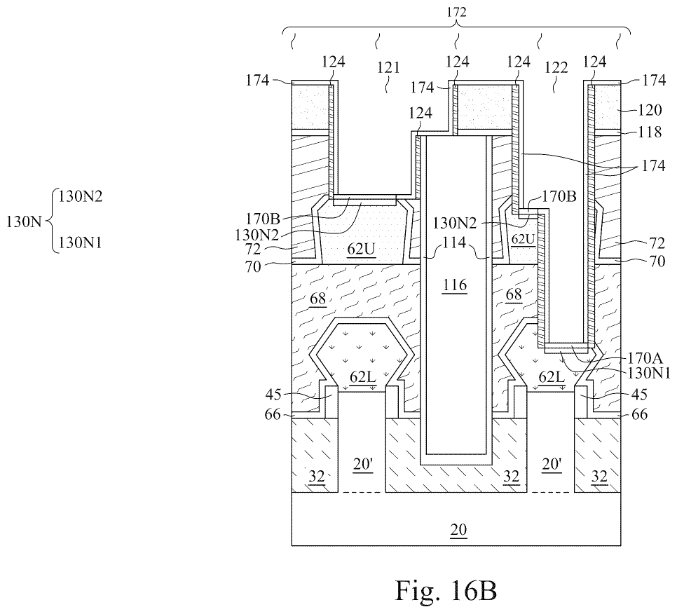

Referring to FIGS. 16A and 16B, silicide regions 170A and 170B are formed. Silicide regions 170A and 170B are over and in physical contact with the underlying n-type silicide regions 130N1 and 130N2, respectively. Silicide regions 170A and 170B (individually and collectively referred to as silicide regions 170) are mid-work-function silicide regions, and have the work function higher than the work function of the underlying n-type silicide regions 130. In accordance with some embodiments, silicide regions 170A and 170B are formed of or comprises titanium silicide, while other silicide's such as VSi, ZnSi, NbSi, AlSi, and the like may be used. It has been found that the stacked layers including n-type silicide layers and mid-work-function silicide layers may improve the performance of both of n-type transistors and p-type transistors.

The formation of silicide regions 170A and 170B may be essentially the same as n-type silicide regions 130N1 and 130N2. For example, the formation process may include conducting the precursor including the corresponding metal (such as Ti), conducting Ar and/or H₂, and turning on plasma, and heating wafer 2. The metal in the precursor reacts with the silicon and/or germanium in the lower source/drain regions 62L and upper source/drain regions 62U to form silicide regions 170A and 170B. For example, the Si and Ge diffuse through the n-type silicide regions 130N1 and 130N2 to react with the metal.

In accordance with some embodiments, when silicide regions 170A and 170B are formed, metal layer 174 is formed on the surfaces of the exposed dielectric regions. Metal layer 174 comprises the elemental metal (rather than metal compounds) of the corresponding metal such as Ti, depending on the metal in the precursor.

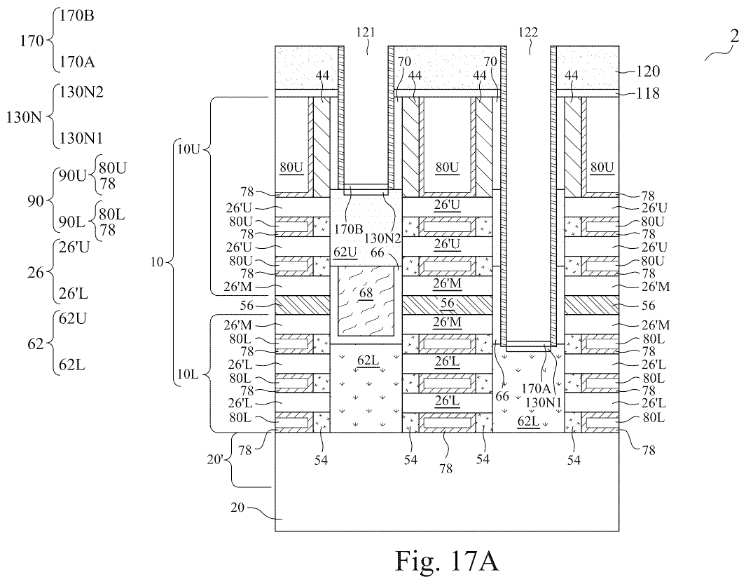

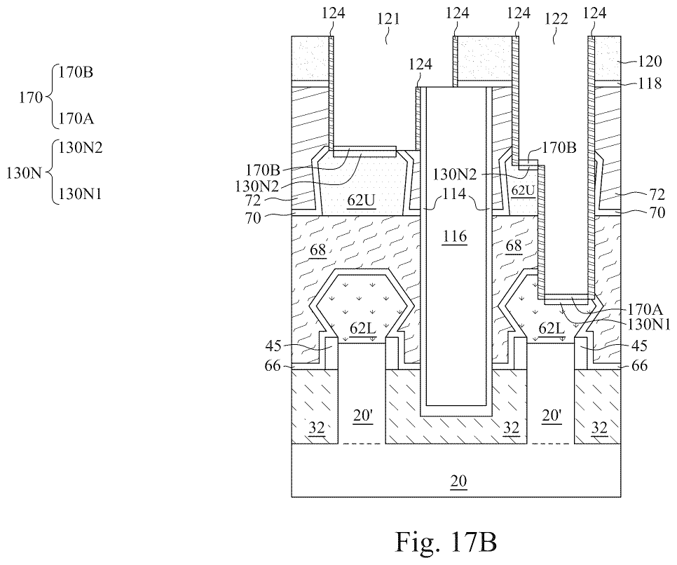

In accordance with some embodiments, the metal layer 174 is removed through etching process 172, which may be essentially the same as the etching process 134 that is discussed referring to FIGS. 6A and 6B. For example, the metal halide (such as TiCl₄) as aforementioned may be used as the etching gas, wherein no plasma is turned on, and no Ar and H₂ are introduced. The metal layer 174 is thus removed, and the resulting structure is shown as in FIGS. 17A and 17B.

In accordance with alternative embodiments, the metal layer 174 is not removed, and a subsequent vacuum break process may result in the formation of metal oxides. The processes as shown in FIGS. 20 through 23 may then be performed to reduce the metal oxide back to elemental metal.

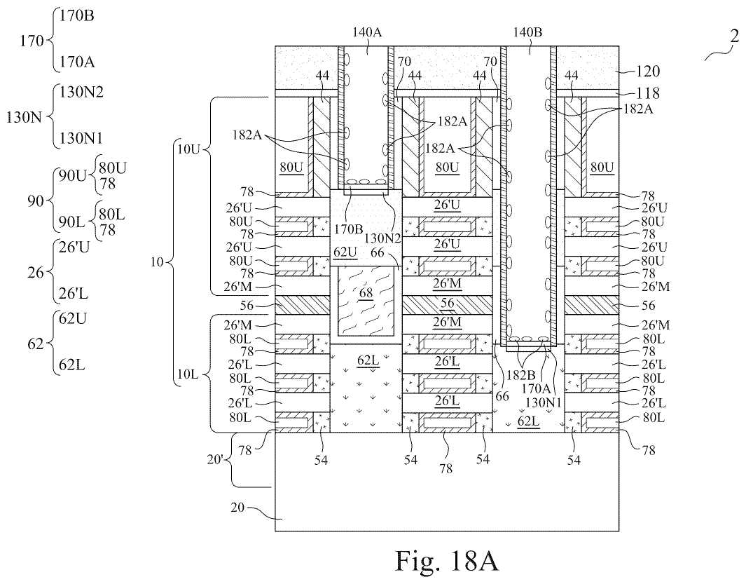

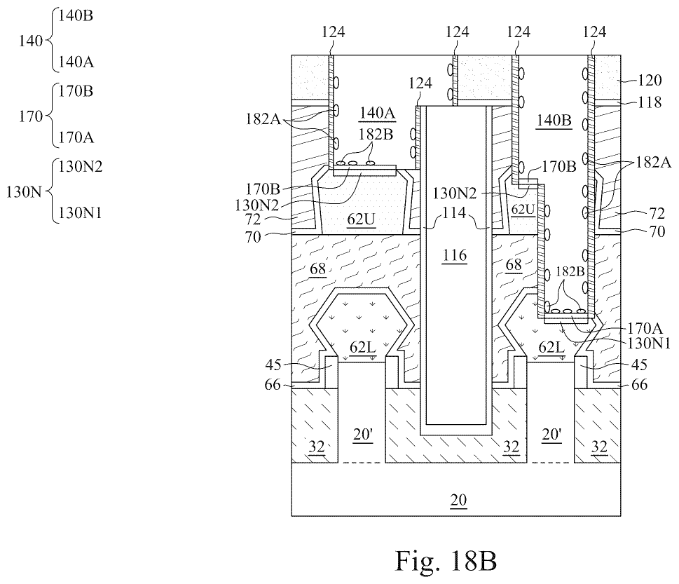

FIGS. 18A and 18B illustrate the formation of contact plugs 140A and 140B. The formation process may be essentially the same as that in FIGS. 8A and 8B. The details are thus not repeated herein. In accordance with some embodiments, when the processes as shown in FIGS. 20 through 23 are performed, metal islands 182A and 182B, which may be discrete islands or a continuous metal layer comprising elemental metal may exist at the edges and the bottoms of contact plugs 140A and 140B. The metal in the metal islands 182A and 182B may be the same metal used for forming silicide regions 130N1 and 130N2 and/or silicide regions 170A and 170B. In accordance with alternative embodiments, when the metal layers 132 and 174 are removed by etching processes 134 and 172, the metal islands 182A and 182B will not exist.

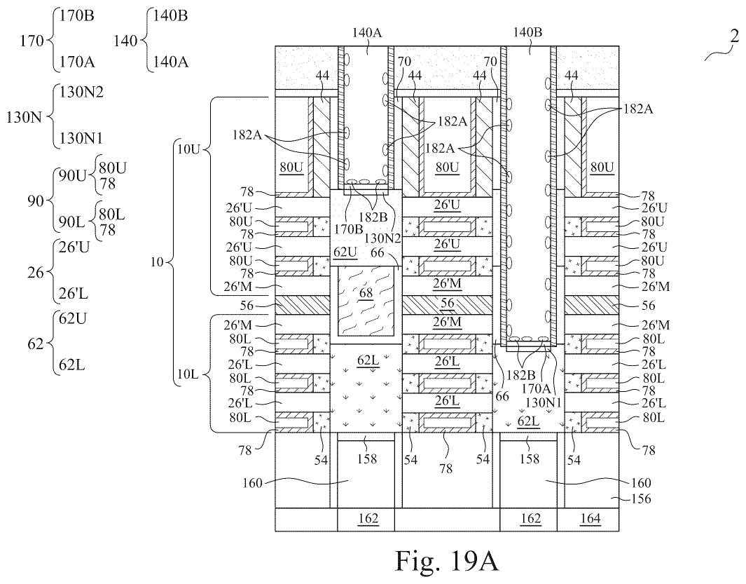

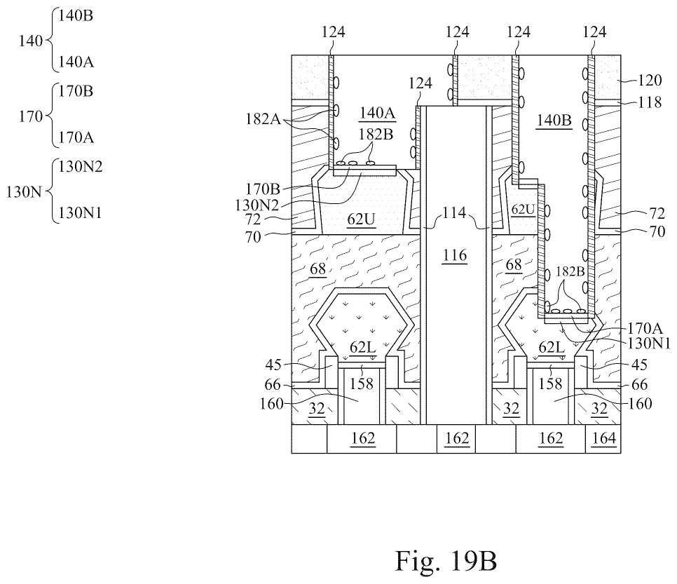

FIGS. 19A and 19B illustrate the formation of backside structures for connecting to the lower source/drain regions 62L and contact plug 116 from the backside of wafer 2. The materials, the structures, and formation processes may be essentially the same as discussed referring to FIGS. 9A and 9B, and are not repeated herein.

FIGS. 20 through 23 illustrates some process steps that may be performed as parts of the processes as shown in FIGS. 1A and 1B through FIGS. 9A and 9B, the processes as shown in FIGS. 10A and 10B through FIGS. 13A and 13B, or the processes as shown in FIGS. 14A and 14B through FIGS. 19A and 19B. The processes as shown in FIGS. 20 through 23 may be inserted after the formation of silicide regions, and before the formation of contact plugs 140A and 140B.

Referring to FIG. 20, silicide regions 176 are formed. The structure as shown in FIG. 20 may represent the structure shown in FIGS. 6A and 6B (when metal layer 132 is not to be removed) or FIGS. 7A and 7B, the structure shown in FIGS. 10A and 10B (when metal layer 132 is not to be removed) or FIGS. 11A and 11B, or the structures as shown in FIGS. 16A and 16B (when metal layers 132 and/or 174 are not removed) or FIGS. 17A and 17B. The silicide regions 176 in FIG. 20 thus may represent the corresponding silicide regions in these figures.

Next, as shown in FIG. 21, a vacuum break process is performed. The vacuum break process results in the surface parts of silicide regions 176 that are exposed to open air to be oxidized, and metal oxide regions 178 (including metal oxide regions 178A and 178B) are formed. Metal oxide regions 178A are formed on the surfaces of dielectric regions. Metal oxide regions 178B are formed on the surfaces of silicide regions 176. Metal oxide regions 178B, and possibly metal oxide regions 178A, may include the metal and the silicon/germanium in the silicide regions 176. The corresponding metal oxides may be represented as M—Si—OX, wherein M represents the metal, Si represents silicon and/or Ge, and OX represents that the M and Si form oxides.

In accordance with some embodiments, metal oxide regions 176A may include M—Si—OX, which may be formed on dielectric liners 124 by reacting the metal with oxygen in the open air, and with SiN when dielectric liners 124 comprises SiN. Otherwise, when dielectric liners 124 comprise silicon oxide, the resulting metal oxide regions 176A comprise metal oxides, rather than M—Si—OX. Accordingly, metal oxide regions 178A, which are formed on dielectric liners 124 and the top surfaces of dielectric regions, may comprise Mi—Si—OX or metal oxides. Metal oxide regions 178B, which are the oxidized portions of silicide regions 176, may comprise Mi—Si—OX. It is appreciated that metal oxide regions 178A and 178B may form discrete islands separated from each other, or may form continuous layers.

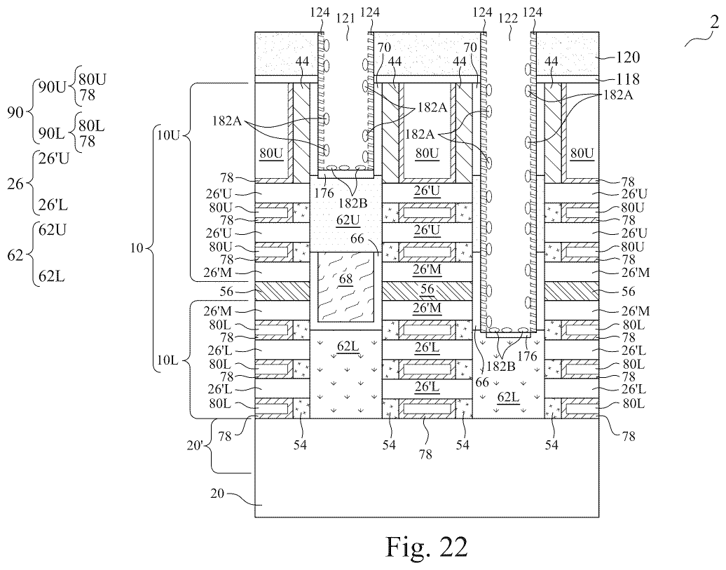

FIG. 21 further illustrates the reduction process 180, which is also referred to as a pre-clean process. The reduction process 180 is performed to reduce the metal oxide regions 178 back to metal regions 182 (including metal regions 182A and 182B), which comprise the elemental metal (rather than metal compounds). The resulting structure is shown in FIG. 22.

The elemental metal is the same as the metal in the underlying silicide regions. In accordance with some embodiments, the reduction process 180 is performed through a soaking process using a reduction gas comprising a metal halide(s). The reduction gas may be selected from the same candidate group of process gases as used in etching process 134 (FIGS. 6A and 6B). In accordance with some embodiments, the reduction gas may comprise WCl₅, TiCl4, and/or the like. In the reduction process 180, no plasma is turned on. Also, no process gases such as H₂, Ar, or the like is applied. There may not be RF power applied also.

It is appreciated that same process gas may be used for the etching processes 134 (or 172) and the reduction process 180. Whether the result is etching or reduction is related to the gases and process conditions. For example, TiCl₄ is more likely to reduce TiOx back to titanium, and is more likely to etch titanium. The elemental metal that is reduced from metal oxides, when further exposed to the process gases, may also be etched. Accordingly, process conditions such as some process gas, lower flow rate of the process gas, shorter reaction time, and the like may result in the reduction process 180, while other selected process gases, higher flow rate of the process gas, longer reaction time, and the like may result in the etching processes 134 and 172.

As shown in FIG. 22, in accordance with some embodiments, elemental metal regions 182 (including elemental metal islands 182A and/or 182B) are formed, which include the same metals as the silicide regions whose formation results in metal layers. Furthermore, in accordance with some embodiments in which WCl₅ is used, element tungsten may be left as parts of elemental metal regions 182 in addition to the metals in metal layers 132 and 174.

FIG. 23 illustrates the formation of contact plugs 140A and 140B, which are also shown in FIGS. 9A and 9B, FIGS. 13A and 13B, or FIGS. 19A and 19B. The elemental metal regions 182 may act as nucleation layers for the better deposition for forming contact plugs 140A and 140B. It is thus less likely to have voids formed in contact plugs 140A and 140B. By converting the metal oxides into elemental metal regions, the contact resistance between the resulting contact plugs and the silicide regions is also reduced.

The embodiments of the present disclosure have some advantageous features. By removing the metal layers formed in the contact openings, it is easier to form contact plugs since the space occupied by the contact openings is released for forming contact plugs. By reducing the metal oxides formed due to vacuum break to elemental metal, the adverse resistance increase due to the metal oxides is reduced, and the formation process of contact plugs is easier due to that the elemental metal is used as a nucleation layer.

In accordance with some embodiments of the present disclosure, a method comprises forming a source/drain region; forming a contact etch stop layer over the source/drain region; forming an inter-layer dielectric over the contact etch stop layer; performing an etching process to form a contact opening in the inter-layer dielectric and the contact etch stop layer, wherein the source/drain region is exposed to the contact opening; performing a first silicide formation process to form a first silicide region on a surface of the source/drain region; performing a first etching process to remove a metal that is deposited on dielectric regions, wherein the dielectric regions are exposed during the first silicide formation process; and forming a contact plug in the contact opening.

In an embodiment, the first etching process is performed in a plasma-free and a hydrogen-free (H₂-free) environment. In an embodiment, the source/drain region comprises germanium, and the method further comprises: before the first silicide formation process, performing a selective deposition process to form a second silicide region over and contacting the source/drain region, wherein the first silicide region is over and contacting the second silicide region. In an embodiment, the first silicide region is an n-type silicide region, and the second silicide region is a p-type silicide region.

In an embodiment, the first etching process is performed using a first metal halide as an etching gas, and the first silicide formation process is performed using a second metal halide as a precursor. In an embodiment, the first metal halide and the second metal halide comprise a same metal. In an embodiment, the method further comprises, after the first silicide formation process, performing second silicide formation process to form a second silicide region over and contacting the first silicide region; and after the second silicide formation process, performing a second etching process to remove an additional metal that is deposited on the dielectric regions. In an embodiment, the second silicide formation process is performed after the first etching process.

In an embodiment, the method further comprises, after the first silicide region is formed, performing a vacuum break to reveal the first silicide region to open air, wherein a metal oxide is formed in the contact opening; and after the vacuum break, conducting a metal halide gas to reduce the metal oxide back to elemental metal. In an embodiment, the first etching process is further performed using the metal halide gas. In an embodiment, the method further comprises, before the first silicide formation process, forming a dielectric liner in the contact opening.

In accordance with some embodiments of the present disclosure, a method comprises forming a lower source/drain region; forming a first contact etch stop layer over the lower source/drain region; forming a first inter-layer dielectric over the first contact etch stop layer; forming a upper source/drain region over the first inter-layer dielectric, wherein the upper source/drain region overlaps the lower source/drain region; forming a second contact etch stop layer over the upper source/drain region; forming a second inter-layer dielectric over the second contact etch stop layer; performing a first etching process to form a contact opening in the first contact etch stop layer, the first inter-layer dielectric, the second contact etch stop layer, and the second inter-layer dielectric; selectively forming a first silicide region over the lower source/drain region, wherein at a time the selectively forming the first silicide region is finished, a top surface of the upper source/drain regions is exposed; forming a second silicide region comprising a first portion over and contacting the first silicide region, and a second portion over and contacting the upper source/drain region; performing a second etching process, wherein a metal layer in the contact opening and deposited by the forming the second silicide region is removed; and forming a contact plug contacting the first portion and the second portion of the second silicide region.

In an embodiment, at a starting time of the forming the second silicide region, dielectric regions facing the contact opening are exposed. In an embodiment, the second silicide region and the metal layer are formed simultaneously. In an embodiment, the second silicide region and the second etching process are performed using halide gases. In an embodiment, during an entire period of time after the first silicide region is formed and before the second silicide region is formed, no etching process is performed to remove additional metals in the contact opening.

In accordance with some embodiments of the present disclosure, method comprises forming a lower source/drain region; forming a first contact etch stop layer over the lower source/drain region; forming a first inter-layer dielectric over the first contact etch stop layer; forming an upper source/drain region over the first inter-layer dielectric, wherein the upper source/drain region overlaps the lower source/drain region; forming a second contact etch stop layer over the upper source/drain region; forming a second inter-layer dielectric over the second contact etch stop layer; forming a first silicide region over the lower source/drain region, wherein the first silicide region comprises a p-type silicide region and a first portion of an n-type silicide region over the p-type silicide region; forming a second silicide region over the upper source/drain region, wherein the second silicide region comprises a second portion of the n-type silicide region; and forming a contact plug connecting the first silicide region to the second silicide region.

In an embodiment, the second portion of the n-type silicide region is between, and is in physical contact with, the upper source/drain region and the contact plug. In an embodiment, the contact plug comprises a homogeneous material that is in contact with both of the first silicide region and the second silicide region. In an embodiment, the p-type silicide region physical contacts the lower source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a source/drain region;
forming a contact etch stop layer over the source/drain region;
forming an inter-layer dielectric over the contact etch stop layer;
performing an etching process to form a contact opening in the inter-layer dielectric and the contact etch stop layer so that dielectric regions are exposed to the contact opening, wherein the source/drain region is exposed to the contact opening;
performing a first silicide formation process to form a first silicide region on a surface of the source/drain region;
performing a first etching process to remove a metal that is deposited on dielectric regions; and
forming a contact plug in the contact opening.

2. The method of claim 1, wherein the first etching process is performed in a plasma-free and a hydrogen-free (H₂-free) environment.

3. The method of claim 1, wherein the source/drain region comprises germanium, and the method further comprises:
before the first silicide formation process, performing a selective deposition process to form a second silicide region over and contacting the source/drain region, wherein the first silicide region is over and contacting the second silicide region.

4. The method of claim 3, wherein the first silicide region is an n-type silicide region, and the second silicide region is a p-type silicide region.

5. The method of claim 1, wherein the first etching process is performed using a first metal halide as an etching gas, and the first silicide formation process is performed using a second metal halide as a precursor.

6. The method of claim 5, wherein the first metal halide and the second metal halide comprise a same metal.

7. The method of claim 1 further comprising:
after the first silicide formation process, performing second silicide formation process to form a second silicide region over and contacting the first silicide region; and
after the second silicide formation process, performing a second etching process to remove an additional metal that is deposited on the dielectric regions.

8. The method of claim 7, wherein the second silicide formation process is performed after the first etching process.

9. The method of claim 1 further comprising:
after the first silicide region is formed, performing a vacuum break to reveal the first silicide region to open air, wherein a metal oxide is formed in the contact opening; and
after the vacuum break, conducting a metal halide gas to reduce the metal oxide back to elemental metal.

10. The method of claim 9, wherein the first etching process is further performed using the metal halide gas.

11. The method of claim 1 further comprising, before the first silicide formation process, forming a dielectric liner in the contact opening.

12. A method comprising:
forming a lower source/drain region;
forming a first contact etch stop layer over the lower source/drain region;
forming a first inter-layer dielectric over the first contact etch stop layer;
forming a upper source/drain region over the first inter-layer dielectric, wherein the upper source/drain region overlaps the lower source/drain region;
forming a second contact etch stop layer over the upper source/drain region;
forming a second inter-layer dielectric over the second contact etch stop layer;
performing a first etching process to form a contact opening in the first contact etch stop layer, the first inter-layer dielectric, the second contact etch stop layer, and the second inter-layer dielectric;
selectively forming a first silicide region over the lower source/drain region, wherein at a time the selectively forming the first silicide region is finished, a top surface of the upper source/drain regions is exposed;
forming a second silicide region comprising a first portion over and contacting the first silicide region, and a second portion over and contacting the upper source/drain region;
performing a second etching process, wherein a metal layer in the contact opening and deposited by the forming the second silicide region is removed; and
forming a contact plug contacting the first portion and the second portion of the second silicide region.

13. The method of claim 12, wherein at a starting time of the forming the second silicide region, dielectric regions facing the contact opening are exposed.

14. The method of claim 12, wherein the second silicide region and the metal layer are formed simultaneously.

15. The method of claim 12, wherein the second silicide region and the second etching process are performed using halide gases.

16. The method of claim 12, wherein during an entire period of time after the first silicide region is formed and before the second silicide region is formed, no etching process is performed to remove additional metals in the contact opening.

17. A method comprising:
forming a lower source/drain region;
forming a first contact etch stop layer over the lower source/drain region;
forming a first inter-layer dielectric over the first contact etch stop layer;
forming an upper source/drain region over the first inter-layer dielectric, wherein the upper source/drain region overlaps the lower source/drain region;
forming a second contact etch stop layer over the upper source/drain region;
forming a second inter-layer dielectric over the second contact etch stop layer;
forming a first silicide region over the lower source/drain region, wherein the first silicide region comprises a p-type silicide region and a first portion of an n-type silicide region over the p-type silicide region;
forming a second silicide region over the upper source/drain region, wherein the second silicide region comprises a second portion of the n-type silicide region; and
forming a contact plug connecting the first silicide region to the second silicide region.

18. The method of claim 17, wherein the second portion of the n-type silicide region is between, and is in physical contact with, the upper source/drain region and the contact plug.

19. The method of claim 17 further comprising a plurality of discrete metal islands between the second silicide region and the contact plug.

20. The method of claim 17, wherein the p-type silicide region physical contacts the lower source/drain region.
